(19) United States
(12) Patent Application Publication
(10) Pub. No.: US 2024/0268208 A1
(43) Pub. Date: Aug. 8, 2024

(54) A METHOD FOR SELECTIVE PATTERNING OF QUANTUM DOTS IN THE PRODUCTION OF OPTICAL DEVICES

(71) Applicant: IHSAN DOGRAMACI BILKENT UNIVERSITESI, Cankaya (TR)

(72) Inventors: Mehmet Selim HANAY, Ankara (TR); Ramazan Tufan ERDOGAN, Ankara (TR); Mohammed ALKHALED, Ankara (TR); Batuhan Emre KAYNAK, Ankara (TR); Hashim Ziad R ALHMOUD, Ankara (TR)

(73) Assignee: IHSAN DOGRAMACI BILKENT UNIVERSITESI, Cankaya (TR)

(21) Appl. No.: 18/566,657

(22) PCT Filed: May 31, 2022
(86) PCT No.: PCT/TR2022/050503

§ 371 Date: Dec. 3, 2023

(30) Foreign Application Priority Data
Jun. 4, 2021 (TR) 2021/009259

(51) Int. Cl. H10K 71/12; B82Y 20/00; B82Y 40/00; H10K 50/16; H10K 102/00

(52) U.S. Cl. CPC H10K 71/125; B82Y 20/00; B82Y 40/00; H10K 50/16; H10K 2102/331

(57) ABSTRACT

The present invention relates to a patterning method for producing optical displays and electronic/electro-optical devices based on quantum dots. By means of the invention, a pixelated multi-colored display containing quantum dots with no significant contamination can be produced, and quantum dots can be selectively patterned in targeted microscopic fields on an optical surface, with very little contamination.

### TECHNICAL FIELD OF THE INVENTION

The present invention relates to a patterning method for the production of optical displays and electronic/electro-optical devices based on electroluminescent and/or photoluminescent quantum dots.

### STATE OF THE ART

Quantum dot (QDot) display technology is a commercialized advanced technology that can provide high-performance displays in television and other applications. At the heart of this technology, there are pixels based on quantum dots, which are nano-sized and semiconducting crystals. These pixels offer high color purity and long-term material stability compared to alternative technologies. The internal structure of quantum dots determines the electronic and optical properties that are generally superior to other devices. Flat panel displays based on quantum dots are being actively developed by means of the desired optical and material properties of quantum dots. There are two general mechanisms that quantum dots use to emit light, and these are photoluminescence (PL) and electroluminescence (EL). In the photoluminescent mechanism; light from another light source activates individual quantum dot pixels, then the activated quantum dots emit light in their characteristic color. It is not possible to use the photoluminescent mechanism on flexible and stretchable displays. Additional rigid layers are required for flexible, stretchable, and wearable displays. Although few examples of such flexible displays have been produced in research by using specific patterning techniques (transfer printing by using viscoelastic stamps), these techniques cannot be scaled to produce large, flexible displays. In the electroluminescent mechanism; electric current is applied to quantum dots and activates quantum dots to emit light of its characteristic color. The development of quantum dots with electroluminescence mechanism, which can enable the use of cheaper and simpler devices, is not included in the prior art due to some disadvantages while all commercial displays operate with the photoluminescence mechanism. For example, the production of quantum dot displays working with electroluminescence mechanism is difficult. The difficulty here is that the quantum dots are produced by a liquid solution-based process. Electronic displays, on the other hand, require the use of a standard grid structure (pixels) on a planar bottom layer such as glass or silicon. As a result, quantum dots cannot be easily integrated into traditional microfabrication techniques.

In the state of the art, one of the critical factors regarding quantum dot display technology is that while preventing contamination on the one hand, on the other hand, there is no suitable technique that enables the creation of high-quality and high-density quantum dots patterns on the surface. Since quantum dots are often produced as nanoparticles suspended in a liquid, they cannot be easily integrated into conventional electronic devices. In the state of the art; a reliable and quick technique is needed that requires each color pixel to be individually addressed, in which the amount of other impurities is negligible especially for the further development of displays based on electroluminescent quantum dots, and that creates microscopic patterns (for example, pixels or sub-pixels responsible for emitting different colors of light within a pixel) from quantum dots.

There are three main approaches for patterning a surface with electroluminescent quantum dots. These can be classified as: a) photolithography performed by using a photoresist mixed with quantum dots, b) transfer printing performed by using viscoelastic stamps, and c) inkjet printing. All three approaches have some disadvantages. Photolithography and inkjet mechanisms cause residual organic contamination on pixels, which reduces optical performance. On the other hand, transfer printing performed by using viscoelastic stamps is difficult to scale on displays with a large area. There is a need for a large area patterning technique that causes almost no contamination due to these disadvantages. Also, in the prior art, quantum dots were applied to the surface inside the photoresist in patterning methods using photolithography. After photolithography, both quantum dots and photoresist layer remain on the surface, which reduces the optical performance of quantum dots.

Even though the electrohydrodynamic jet printing method, another patterning method used in the prior art, is superficially similar to the electrospray ionization method, high electrical voltage directly supplies a carrier liquid containing quantum dots to a surface in the electrohydrodynamic jet printing method. As such, both the carrier liquid itself and other chemical doping materials that should be present in the carrier liquid are put on the surface together with the quantum dots. Even if the carrier liquid evaporates over time, it can damage the structures previously left on the surface during this process, as well as disrupt the pattern desired to be produced on the surface during liquid flow and evaporation from the surface.

It is necessitated to develop a method for selectively patterning quantum dots in targeted microscopic areas on a surface, with very slight contamination due to limitations and inadequacies in the state of the art such that commercial quantum dot displays are heavy and expensive since photoluminescence mechanism is used, that said photoluminescence mechanism here requires another light source, multiple optical layers, and liquid crystal displays in addition to the quantum dot layer, and that the cross contamination occurs between pixels of different colors for displays based on electroluminescent quantum dots.

### BRIEF DESCRIPTION AND OBJECTS OF THE INVENTION

The present invention describes a method for producing a display in which desired sub-pixels are rendered to contain only the desired type of light-emitting quantum dots.

The present invention discloses a method for producing a display composed of pixels containing quantum dots such that the active optical region of each sub-pixel type (preferably in different colors) creating each pixel on this display is composed of quantum dots of the desired type, and also for selectively patterning quantum dots in targeted microscopic areas on an optical surface so as to minimize both cross-contamination between different sub-pixel types and other contamination from chemicals used in the production for each sub-pixel. For this selective method, quantum dots are ionized by an appropriate mechanism, and these ions are transferred onto a desired surface by means of an ionic lens. The ionic lens used may be a conductive device (conductive lens), on which voltage is applied, or it may also be an insulator device (insulator lens) that has the effect of an ionic lens by accumulating the charges thereon and has a patterned surface thereon. This insulator lens can preferably be realized as a polymer layer with holes thereon. The lens produced from a polymer layer in this way is called a polymeric lens.

In one embodiment of the present invention, the insulator lens consisting of a polymeric layer with patterned holes can be placed on top of a substrate or directly laid, and electrospray ionization process is applied to a liquid solution containing quantum dots, thereby producing electrically charged quantum dots. By means of the known operation of the electrospray ionization process, the quantum dots are transformed into separate and free ions from the liquid and other contaminants. During this process, electrical charge is developed on the polymeric layer, by means of the charged particles and molecules, including some of the quantum dots deposited on the polymeric layer, and therefore, this layer creates an electric field that focuses most of the incoming electrically charged quantum dots into holes on the layer. In this way, it triggers the effect of focusing the quantum dots towards the desired pixel region. Thus, at the end of the process, most of the quantum dots are focused according to the desired pattern and are deposited inside the middle of each hole defined by the polymeric layer. Also, repeating the same procedure with different patterns and quantum dots provides a method for patterning different microscopic fields with different quantum dots.

According to an embodiment of the present invention, the focusing ionic lens is replaced by an electrically addressable conductive mask that is either deposited or placed on the substrate in order to attract or repulse quantum dots to certain areas on the substrate.

According to an embodiment of the present invention, metal electrodes patterned on the substrate are used in addition to the focusing dielectric lens and electrospray ionization of quantum dots; thus, the voltage of the metal electrode and/or its connection to an electrical neutralization reservoir such as electrical grounding is used to either attract or repulse incoming quantum dots; thereby providing a direct electrical connection to the quantum dots inside a pixel, and also providing another layer of selectivity that results in the use of fewer polymeric layers to deposit different types of quantum dots in different areas.

According to an embodiment of the present invention, metal electrodes on the substrate are used in addition to the electrospray ionization of quantum dots; so that the voltage of the electrode and/or its connection to an electrical neutralization reservoir, such as an electrical ground, is used to either attract or push quantum dots; as a result thereof, a direct electrical connection is provided to quantum dots inside a pixel, and also, selectivity is provided for collecting different types of quantum dots in different areas without the need for a polymeric layer for the initial focusing process.

An object of the present invention is to directly deposit electroluminescent quantum dots on target pixels containing electrodes by using electrospray ionization and ionic lenses located close to or directly on the surface desired to be patterned. By means of the present invention, electroluminescent quantum dots can be deposited directly onto target pixels containing electrodes, and in this way, the display can be greatly simplified and so many inner layers are no longer needed in quantum dot displays. The present invention achieves this object by ensuring that the quantum dots, which break free from the solution and spread into the air in the form of individual particles due to electrospray ionization and also gain an electric charge, reach the desired pattern pixels through the electric field created by using the ionic lens.

Another object of the present invention is to deposit electroluminescent quantum dots with less cross contamination. As it is known, during the electrospray ionization process, the liquid solvent molecules in the small droplets carrying the material to be deposited evaporate into the air, and thus, only the material to be deposited reaches the surface. In some cases, salts may be added to the solution to stabilize the electrospray ionization process. In case these salts are selected from salts that can convert to volatile products such as ammonium acetate, these additives will also evaporate into the air during the electrospray process, so that no contamination from salts will be on the surface. Therefore, by means of the present invention, electroluminescent quantum dots with less cross-contamination are deposited, thereby improving both the display performance and the performance of each pixel since quantum dots of each color can be transmitted to different points on the surface with a different ionic lens. By means of electrospray ionization, selectively delivering the purified quantum dots in solvent droplets and molecules to the desired pixels by means of an ionic lens enables the invention to achieve this object.

Another object of the present invention is to apply the electrospray ionization process to a surface containing an ionic lens from a distance and, if necessary, from several sources in parallel, thereby increasing the speed of the production method. The present invention achieves this object by simultaneously operating the same quantum dot solution by several electrospray ionization tips.

Another object of the present invention is to have a flexible structure instead of a rigid structure of the patterned surface, to produce large-scale displays based on quantum dots and to enable the use of flexible, stretchable, and wearable displays. In the present invention, quantum dots can optionally be deposited on a large area and thus large, flexible displays can be produced. In the present invention, this object is achieved by keeping the substrate planar during deposition due to the electrospray ionization of the charged quantum dots from the liquid they are in, and the orientation of their electrical charges in the electric field created by the ionic lens, then delivering the desired quantum dots to the pixels that can neutralize their charges by attracting ions in the surface material and are individually addressed, optionally using a surface material that can be stretched.

### DESCRIPTION OF THE FIGURES

FIG. 1 illustrates the general view of electrospray ionization and the method of depositing quantum dots on addressed electrodes by means of an insulator lens.

FIG. 2 illustrates the sectional view of the quantum dots, as a result of the production step where the quantum dots are deposited by means of the electrospray deposition activity together with the focusing effect of the insulator lens.

FIG. 3 illustrates a sectional view of the surface as a result of the fabrication step of completing the addressable deposition of the quantum dots display device, where additional focusing of the quantum dots into the center of the patterned holes can be seen.

FIG. 4 illustrates the sectional view of the deposition of quantum dots as a result of the proposed fabrication method when addressing electrodes are not used.

FIG. 5 illustrates the sectional view of the quantum dots display with transparent substrate and transparent addressing electrodes as an example of the devices that will be created by the production method of the present invention.

FIG. 6 illustrates the sectional view of the display device, which, with obvious changes made in the production method of the invention, could be formed by the process of properly patterning quantum dots using an insulator lens also to the surfaces with pre-existing patterns of electron or hole transport (transfer) layers.

FIG. 7 illustrates the deposition process of different types of quantum dots in regions determined by the respective insulator mask by using the sequential use of different ionic lenses (After each type of quantum dot is deposited in the desired location, the insulating mask is removed and a new insulating mask suitable for the next type of quantum dot is laid.).

FIG. 8 illustrates the patterning process of different types of quantum dots that can be deposited at different locations on the substrate in order to produce the display device containing the transparent electrodes and the transparent substrate.

FIG. 9 illustrates the top view and two sectional views of a part of the display device with 5 pixels, each consisting of 3 sub-pixels formed by the deposition of 3 different types of quantum dots, as an example of the devices that can be formed by the production method of the present invention.

FIG. 10 illustrates the isometric view of the flexible substrate and top-coated insulator lens for selective patterning of quantum dots, which can be formed by the production method of the present invention.

FIG. 11 illustrates the deposited quantum dots placed on the flexible substrate after the patterning process.

FIG. 12 illustrates the process of transferring pixels from a (sacrificial) substrate that loses material over time onto a transfer substrate.

FIG. 13 illustrates the production method of deposition of quantum dots by using a conductive lens, in which focusing of the quantum dots is achieved by applying a biasing voltage to the electrostatic lens.

FIG. 14 illustrates the production method of deposition of quantum dots by using a patterned, a standalone conductive lens.

FIG. 15 illustrates the microscopic view of 100 nm diameter fluorescent polystyrene nanoparticles deposited on a surface by the proposed method, with the insulator lens still on the surface.

### DESCRIPTION OF ELEMENTS/PARTS/COMPONENTS OF THE INVENTION

The parts and components in the figures are enumerated for a better explanation of the method developed with the present invention, and correspondence of every number is given below:
1. Electrospray ionization tip
2. Insulator lens
3. Patterned openings in insulator lens
4. Electrode
5. Substrate
6. Liquid solution containing quantum dots
7. Quantum dots in the solution
8. Quantum dots that are deposited on the substrate
9. Quantum dots deposited by focusing on the substrate
10. Distance that corresponds to focusing of particles
11. High voltage source
12. Transparent electrode
13. Transparent substrate
14. Electron or hole transport layer
15. Polymeric lens for the deposition of the first color of quantum dots by this invention
16. Polymeric lens for the deposition of the second color of quantum dots by this invention
17. Polymeric lens for the deposition of the third color of quantum dots by this invention
18. Addressing connection of electrodes
19. Display with sub-pixels
20. Flexible substrate
21. Sacrificial substrate
22. Transfer substrate
23. Conductive lens
24. Biasing voltage for conductive lens
25. Standalone ionic lens

### DETAILED DESCRIPTION OF THE INVENTION

The present invention relates to a patterning method for the production of optical displays and electronic/electro-optical devices based on electroluminescent and/or photoluminescent quantum dots. Said patterning method can be used for patterning nanoparticles that convert light into electrical energy by photovoltaic mechanism and nanoparticles that convert light into electrical energy with photothermal effect on the desired surface.

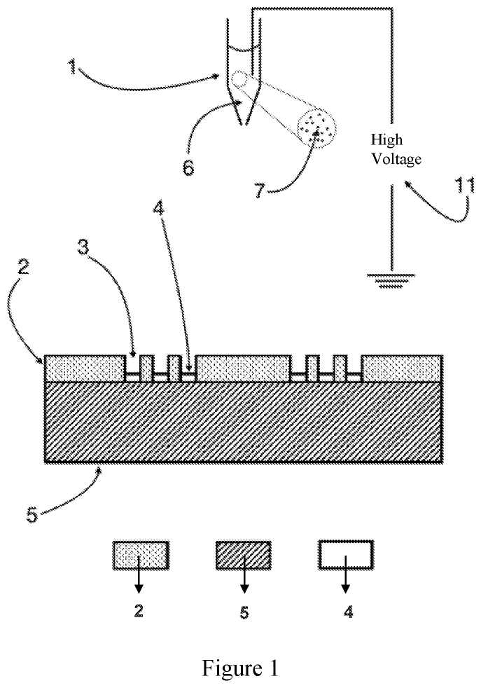

In this invention, a mechanism as in FIG. 1 is established to form sub-pixels by laying the quantum dots of each color at the desired location on the surface. A patterning method in the production of quantum dot-based optical displays and electronic/electro-optical devices, which is the subject of the present invention, comprises the following process steps:
i. Laying the material that will form the ionic lens on a substrate, on which electrodes and/or additional materials that will facilitate the transmission of electric current have been previously treated,
ii. Forming the desired sub-pixel pattern in the form of holes on the material that will form the ionic lens by patterning, and obtaining the ionic lens by aligning the holes that define the sub-pixel on the machined electrodes by using standard alignment methods,
iii. Forming the electrically charged quantum dots in air, in a pure and discrete manner from other materials, by passing the liquid solution containing quantum dots through the process of electrospray ionization, and sending it to the surface desired to be patterned,
iv. Focusing quantum dots through the holes that define the sub-pixel by means of electric force, and thereby patterning the majority of the quantum dots on the desired electrodes by means of the electrical charges accumulated thereon in case the ionic lens is an insulator lens, and by means of the electrical potential applied thereon in case the ionic lens is a conductive lens,
v. Removing the layer acting as an ionic lens from the substrate surface by means of a suitable solvent, abrasive, or corrosive,
vi. Repeating the previous processing steps for each different type of quantum dot that is desired to be used by using the appropriate pattern.

Different types of quantum dots are patterned as desired on the electrodes on the substrate surface by means of said patterning method. The steps (i-vi) listed above constitute the main core of the method of the present invention. The advantage of these steps is that, unlike other known methods, the quantum dots are patterned purely at desired locations on a substrate surface.

In addition to these main steps, different steps can also be included in the method. There are many different layers, especially in displays containing electroluminescent quantum dots, and these other layers can be produced in different combinations, either before or after the steps (i-vi) mentioned above by using standard methods. Obviously, all combinations of standard methods in different orders can be used to produce the display in addition to the quantum dots patterned at desired locations by means of the main steps (i-vi) provided by the present invention.

In an embodiment of the present invention, in addition to the steps (i-vi) of said patterning method, if desired, the electron transfer layer (for example, zinc oxide (ZnO) or magnesium zinc oxide (MgZnO) nanoparticles) used in the electroluminescence quantum dot display method can also be patterned by the method of the present invention. To perform this additional patterning, the following step is performed between the aforementioned steps (ii) and (iii):
a. applying the electrospray ionization process to the solution containing nanoparticles with electron transfer layer function and patterning the nanoparticles on the substrate surface by using the ionic lens to be used for quantum dots in this step.

Thus, before the quantum dots are patterned on the substrate surface, the electron transfer layer is also pre-patterned in the same areas. The benefit of such adding is that two different layers that need to be overlapped are automatically aligned by using the same ionic lens repeatedly.

In an embodiment of the present invention, before the quantum dots are sent to the prepared surface,

The process steps of
a) sending nanoparticles having the feature to facilitate the electron flow to zinc oxide (ZnO), magnesium-doped zinc oxide (Mg-doped ZnO) and quantum dots that act as electron transfer layer to the surface by electrospray ionization,
b) focusing the nanoparticles through the holes that define the sub-pixel by means of electrical force by the ionic lens and thereby patterning the majority of the quantum dots on the desired electrodes,
are performed.

In another embodiment of the present invention, the electron transfer layer can be pre-patterned on the same substrate surface by means of a different method. In another embodiment of the present invention; in said method, instead of the electron transfer layer, a different material, e.g. hole transfer layer, can be used to pattern the quantum dots.

After the quantum dots are patterned on the electron transfer layer at desired locations, the production of the display can be completed with the standard processes by means of the method of the present invention. For example, after the patterning method of the present invention;
b. by applying the process steps of, laying the hole transfer layer in a suitable gas environment by using a spin coating device,
c. depositing the hole injection layer,
d. joining a substrate with electrodes on this stack that is formed,
   a monochrome or multi-colored display is produced. In another embodiment of the present invention, any other method used as a standard for display production can also be used. For example, in addition to these layers used, the hole injection layer, which is used as a standard in electroluminescent quantum dot technology, can be included in this production process, preferably by depositing it with spin coating.

Said electrospray ionization mentioned in the method of the present invention is the process of forming small electrically charged droplets from the tip by applying a high voltage to the tip after delivering the solution containing quantum dots to the tip, these droplets evaporating as they travel through the air, individual electrically charged quantum dots being formed in the air by eventually shrinking as a result of the undergoing the Rayleigh fission phenomenon, and these quantum dots moving towards the substrate, which is held at a lower electric potential compared to the tip of the electrospray ionization tip.

The biggest advantage of said patterning method is the deposition of quantum dots in desired places with low contamination, and the combination of electrospray ionization and insulator lens. In previous methods using photolithography, quantum dots were applied to the surface inside the photoresist. After photolithography, both the quantum dots and the photoresist layer remained on the surface, which reduced the optical performance of the quantum dots. In the method described in the present invention, photoresist and quantum dots are separated from each other. Thus, while the photoresist is applied to the surface with the desired pattern, the quantum dots are sent to the surface by electrospray ionization from a certain distance, in the process of electrospray ionization, it forms free and low contamination quantum dots in the air, and as the quantum dots approach the surface, they are put into the desired holes by means of the insulator lens feature of the photoresist layer.

In the method proposed in the present invention, the liquid carrying the quantum dots evaporates while moving from the tip producing the electrospray ionization towards the substrate surface, thus, it does not reach the surface. It may be necessary to add various salts to the carrier liquid in order to make the electrospray ionization process more effective (for example, for the purpose of reducing the size of the first droplets produced by electrospray ionization by increasing the conductivity of the solution). In case these salts are chosen from volatile salts, preferably ammonium acetate or ammonium bicarbonate, it provides very low contamination in terms of laying quantum dots since these salts will also be released into the air in the gas phase after electrospray ionization.

In the present invention, the electrodes and the substrate may be transparent or may be made of a non-transparent material. The same production process can be performed by using materials with different optical properties in different applications.

In another embodiment of the present invention, the material of the ionic lens can be conductive or insulating. In case the ionic lens is conductive, a voltage can be applied to the ionic lens to focus the particles sent to the desired location by electrospray ionization. The ionic lens used in this case can be selected from any conductive material (for example, any metal or conductive elements such as carbon).

In another embodiment of the present invention, the ionic lens can be positioned on the substrate or between the electrospray ionization tip and the substrate.

In another embodiment of the present invention, the ionic lens material can be insulating. A structure that can perform said focusing function is obtained as long as the holes in the desired dimensions are opened on an insulator layer by any method. The insulator ionic lens material can be selected from polymeric, alumina or ceramic, etc. materials such as silicon dioxide.

In another embodiment of the present invention, on the surface, instead of the electron transfer layer, another layer in the general device architecture, such as the hole transfer layer, can also be found. In addition, the fact that these layers are patterned on the surface by a method other than electrospray ionization does not affect the production process.

In another embodiment of the present invention, a method for patterning quantum dots in specific areas (sub-pixels) determined by the ionic lens on a substrate (5) is provided. As seen in FIG. 1, the liquid solution (6) containing the quantum dots is placed inside an electrospray ionization tip (1). This tip can also have a microfluidic channel, and the liquid solution (6) containing the quantum dots can be placed inside the ionization tip (1) by means of said microfluidic channel. The liquid solution (6) containing the quantum dots may be formed with any solvent suitable for electrospray ionization, including, but not limited to, water, methanol, ethanol, other alcohols, acetonitrile, chloroform, hexane, octane, other alkanes, and other organic solvents. Volatile additive chemicals such as salts such as ammonium acetate, acids such as acetic acid, and bases such as ammonia can be added to the solution in order to facilitate the electrospray ionization process. After the solution is added into an electrospray ionization tip (1), a potential difference is created between the tip and a counter electrode (4) near thereof in order to trigger the electrospray ionization. This counter electrode (4) may be the substrate (5) itself, or it may be any other suitable electrode used to remove ions from the tips, e.g with a central hole, such as in a ring, which does not prevent the passage of ions. One method of generating the electrical difference may be applying a high voltage to the solution or electrospray tip (1) with a high voltage source (11).

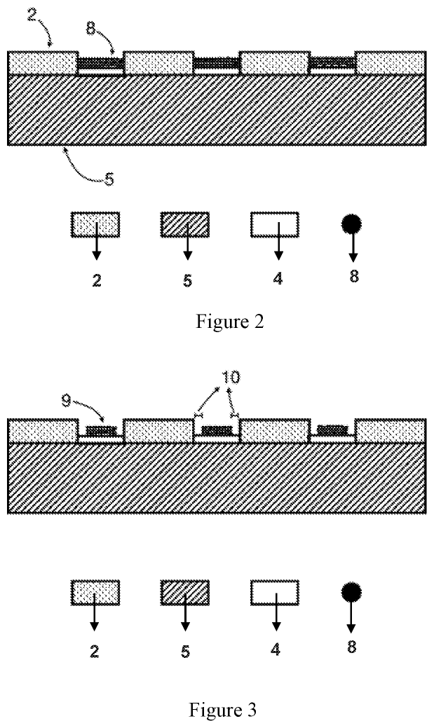

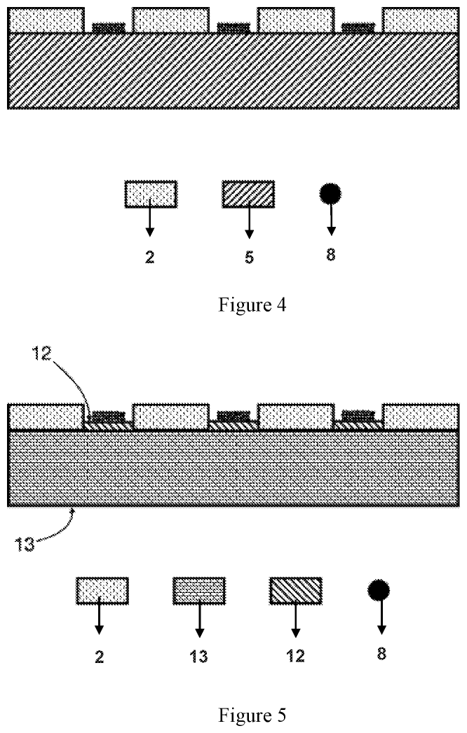

In another embodiment of the present invention, an insulator layer with patterned holes is placed on the substrate (5), where the specific pattern of quantum dots will be produced. The insulator layer with patterned holes has the insulator lens (2) as shown in FIG. 1. Here, the insulator lens (2) can be any type of photoresist that can be deposited by spin coating onto the substrate 5 so as to have holes defined by photolithography or can be an insulator material that has holes machined thereon with other microfabrication methods and then placed on the surface. The electrically charged particles produced by electrospray ionization and hitting this polymeric layer trigger the accumulation of charge on the surface, and effectively converts the polymeric layer into an ionic lens. As a result, most of the incoming quantum dots are focused by the electric field generated on the central portion of the holes of the polymeric layer, as shown in FIG. 2. As shown in FIG. 3, where most of the patterned quantum dots (9) are located at some distance (10) beyond the boundary of the holes of the insulator lens, due to electrostatic focusing, the final patterning on the substrate may be narrower than the original pattern on the polymeric lens. The advantage of this focusing method is that the pixel size can also be smaller than the size of the holes on the insulator lens, thereby increasing the pixel density. After the desired quantum dots are placed, the polymeric layer can be removed by a suitable process such as dissolution, chemical or plasma etching without removing the deposited quantum dots.

According to another embodiment of the present invention, the electrospray tip (1) can be provided with additional components such as nebulizing gas, shielding gas and drying gas in order to facilitate the electrospray ionization. The polarity of electrospray ionization (e.g. positive mode or negative mode), in addition to the type of electrospray ionization (e.g online or offline, nano-ESI etc.) can be chosen so as to match the properties of quantum dots and substrates at any stage of deposition.

In another embodiment of the present invention, for electrospray ionization, electrospray ionization can be performed by placing a solution in any conductive material with any substrate or channel instead of the tip.

In another embodiment of the present invention, the insulator lens utilized to focus the ions may be an Electron Beam Lithography (EBL) resistor (resist material) such as poly(methyl methacrylate) (PMMA), and the pattern is created with the EBL process. In another embodiment of the present invention, the insulator lens used for focusing ions may be a suitable polymer for soft lithography such as polydimethylsiloxane (PDMS), and the pattern is created by soft lithography. According to another embodiment of the present invention, ionic lens is a conducting or semiconducting solid with patterned microscopic holes, and it is placed on top of the substrate by direct contact or using a mask aligner or using an external positioning system. In another embodiment of the present invention, the ionic lens is not in contact with the substrate, and it is even placed on top of the substrate at a distance of up to 10 cm such that the surface quality of the substrate is not compromised, and patterns with dimensions smaller than those on the ionic lens are obtained by means of the extra space between the substrate and the ionic lens.

In another embodiment of the present invention, the material that will form the ionic lens may be an insulator or conductive polymer obtained by any microfabrication method.

In another embodiment of the present invention, in order to facilitate the process of electrospray patterning of quantum dots, the substrate (5) comprises pre-patterned electrodes (4) that present themselves as the electrical connection to the quantum dots and also as the conductive surface on which the discharge of the incoming electrically charged quantum dots is performed, and that is aligned with the insulator lens (2).

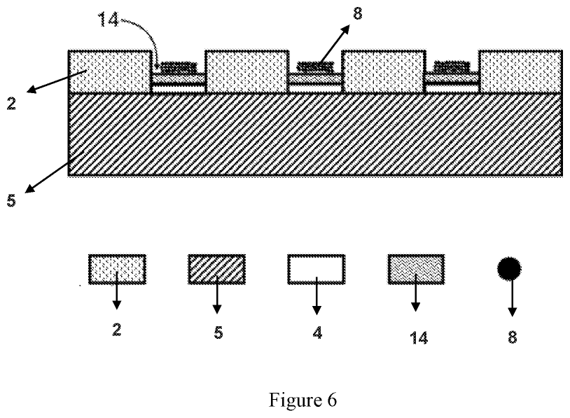

In an embodiment of the present invention, as shown in FIG. 4, a stack of material in FIG. 4 can be obtained when the substrate (5) does not comprise any pre-patterned electrodes during production. Here, the patterning and focusing of the quantum dots is generally performed by the electrostatic repulsion of the insulator lens (2) and thus focusing the incoming ions.

In another embodiment of the present invention, as shown in FIG. 5, production can also be performed when a transparent substrate (13) and transparent electrodes (12) are used since the process of focusing ions does not depend on whether the materials are opaque or transparent. In other embodiments, any combination of transparent/opaque substrates/electrodes may be used.

In another embodiment of the present invention, as shown in FIG. 6, materials such as the Electron Transport Layer (ETL) and Hole Transport Layer (HTL) that can facilitate charge transport into the quantum dots to trigger electroluminescence are pre-patterned before the quantum dots are deposited. In another embodiment of the present invention, the ETL or HTL layers are deposited on pre-patterned electrodes, while in another embodiment, the ETL and HTL layers are patterned directly onto a substrate. Patterning of ETL and HTL layers can be performed by using the Electrospray Ionization and insulator lens mentioned in the present invention, or by any other method suitable for patterning ETL and HTL materials. It is obvious that the hole injection layer utilized as standard with electroluminescent quantum dots can also be patterned sequentially with the HTL layer.

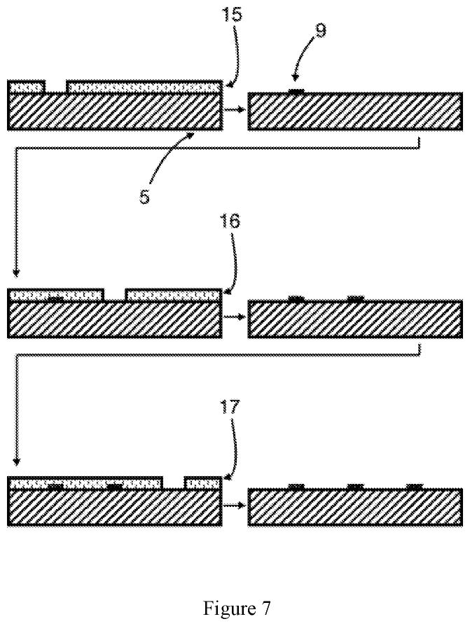

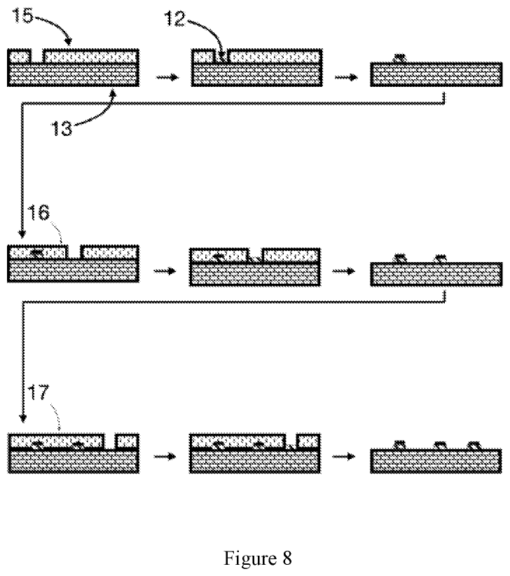

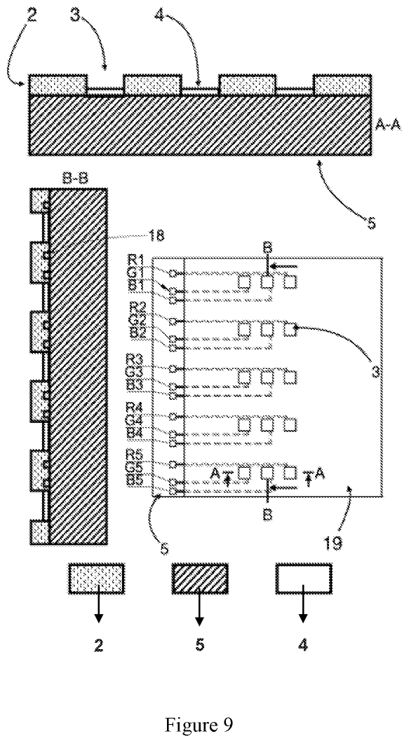

For the purpose of patterning different types of quantum dots in different areas, as shown in FIG. 7 and FIG. 8, the process is repeated on the same substrate by using a different polymeric lens and a different type of quantum dot. Alignment markers on the substrate can be used to align different layers relative to each other. FIG. 8 illustrates an embodiment where both the substrate and the electrodes are transparent. In other embodiments, it is clear that any combination of transparent/opaque substrates/electrodes can be used. The quantum dots in each deposition step can differ in the color of the light they emit. In this manner, the present invention allows for patterning the quantum dot-based pixels composed of sub-pixels of different colors and producing multi-color display devices.

In another description of the invention, only a single insulator lens is used, and as shown in FIG. 9, different types of quantum dots are sequentially deposited on the desired electrodes by electrically controlling the voltage of the electrodes. While the first type quantum dots are electrosprayed, the electrodes indicated by prefix R can be held at an appropriate voltage level so as to attract the incoming type-R charged quantum dots, meanwhile, other electrodes indicated by prefixes G and/or B can be held at different voltage levels to repulse type-R quantum dots or they can be left electrically floating. In way of example, if the positive mode of electrospray is used to generate positively charged quantum dots, then the electrodes with prefix R can be held at negative voltage level or ground voltage, while electrodes labeled with prefix G and/or B are held at positive voltage levels. When the deposition of type-R quantum dots is finished, then the same procedure is repeated with other types of quantum dots and readjusting the voltages on the electrodes accordingly. In this case, when type-G quantum dots are electrosprayed, the voltages on electrodes labeled with prefix G are adjusted to be attractive for the incoming quantum dots, while the voltages on electrodes labeled with prefix R and/or B are adjusted to be repulsive. Similarly, when type-B quantum dots are electrosprayed, the voltages on electrodes labeled with prefix B are adjusted to be attractive for the incoming quantum dots, while the voltages on electrodes labeled with prefix R and/or G are adjusted to be repulsive.

Although in FIG. 9, the electrodes are that control the pixels are illustrated to be on the substrate, it is obvious that the layout of embodiments of the invention can have any other form suitable for the production of the displays and devices. In particular, the electrodes can pass through the substrate, and make electrical connections to the next circuit at the other side of the substrate. In this way, known technologies such as TSV (through silicon via) method can also be used to form electronic connections to pixels.

In another embodiment of the present invention; the selective patterning of quantum dots is accomplished without the use of an insulator lens, and solely by the attraction/repulsion of ions by the application of suitable voltages on metal electrodes. In this embodiment, a small amount of unspecific deposition is expected on the substrate not covered by the metal electrodes. However, since the quantum dots in these areas will remain passive due to the lack of electronic connections, the presence of such quantum dots will not interfere with the operation of the device.

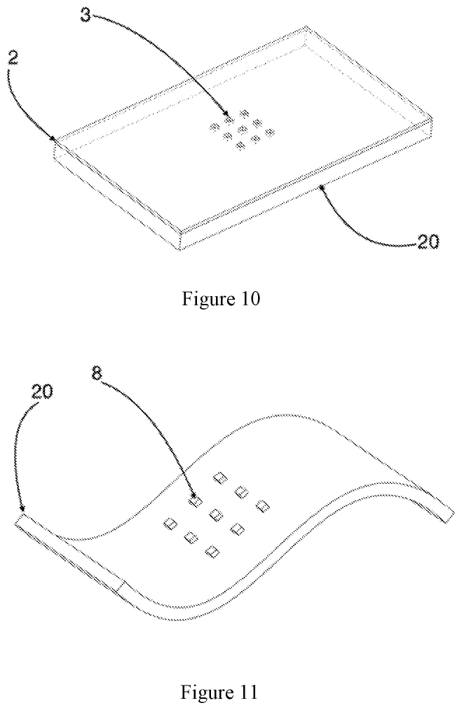

In another embodiment of the present invention, the substrate is not a rigid solid, but a flexible and/or stretchable and/or wearable material. During the deposition of quantum dots, as illustrated in FIG. 10, the flexible substrate (20) is kept flat, and the insulator lens (2) is placed on top of it.

In another embodiment of the present invention, the insulator lens may be photoresist, and the placement is performed by spinning, organic thermal evaporation, or drop-casting. In another embodiment, the insulator lens is a solid structure with microscopic patterns and is placed in contact on top or above the flexible substrate. After the deposition, the flexible substrate may be mechanically deformed as shown in FIG. 11, and the patterned quantum dots (8) on the substrate will conform to the mechanical deformation. Clearly, metallic electrodes suitable for flexible substrates can be supplemented to electrically address the pixels.

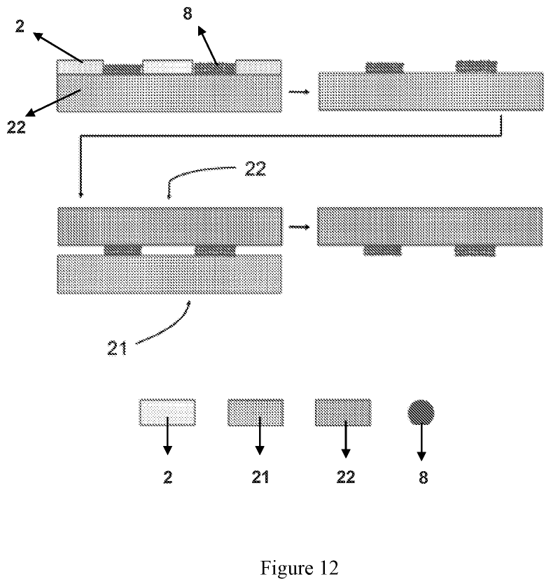

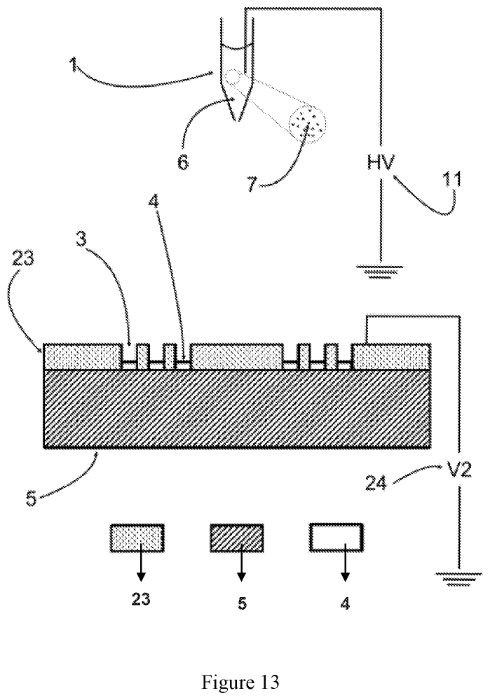

In another embodiment of the present invention, the pixels are initially deposited on a sacrificial substrate (21) by using an appropriate lens. The sacrificial substrate is then used to transfer the deposited pixels onto another desired transfer substrate (22) that can either be solid or flexible, insulator or conductive, or with addressable electrodes. As shown in FIG. 12, transfer can be performed through any suitable methods such as force stamping, heat transfer, nanoimprinting, hot embossing. The sacrificial substrate is removed after pixel transfer by physical or chemical methods such as peeling, dissolution or corrosive gas etching.

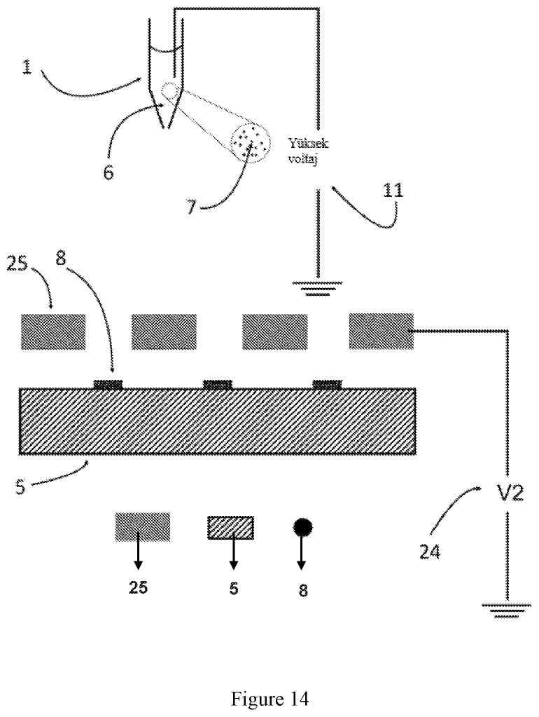

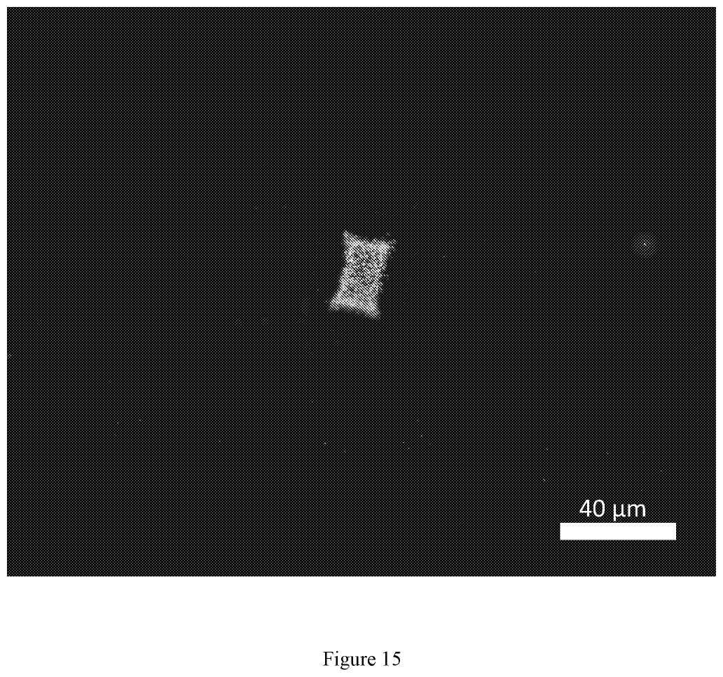

In another embodiment of the present invention, as illustrated in FIG. 13, the ionic focusing of charged quantum dots is performed by a conductive lens (23) kept at a suitable voltage (24) such as at a fraction of the voltage used to generate electrospray ionization (11). In one embodiment, the conductive lens may be a metal or semiconductor layer deposited on top of the substrate region and patterned by using standard micro/nano-fabrication processes. In another embodiment, the conductive lens may be a stand-alone metal or semi-conductor piece, placed slightly above the substrate (from touching up to 10 cm) as shown in FIG. 14.

In another embodiment, other nano-sized particles with optical functions in place of quantum dots can also be used to produce optical displays, optoelectronic devices, solar panels, etc. Photovoltaic or thermoelectric materials are deposited by using electrospray ionization and using ionic focusing to produce solar panels. In this way, micro- and nano-sized materials that can convert light to electricity and are difficult to deposit on substrates with conventional micromanufacturing can also be patterned. Thus, the advantages of forming such materials from nano and micro-sized modules, for example, that the electron and hole pair separated by the light, reach the material surface without recombining in the material and provide electrical energy conversion will be utilized.

1. A patterning method for the production of quantum dot-based optical displays and electronic/electro-optical devices, characterized by comprising the process steps of,
i. Depositing the material that will form the ionic lens on a substrate on which electrodes and/or additional materials that will facilitate the transmission of electric current have been previously patterned,
ii. Forming the desired sub-pixel pattern in the form of holes on the material that will form the ionic lens by patterning, and obtaining the ionic lens by aligning the holes that define the sub-pixel on the machined electrodes by using standard alignment methods,
iii. Forming the electrically charged quantum dots in air, in a pure and discrete manner from other materials, by passing the liquid solution (6) containing quantum dots through the process of electrospray ionization, and sending it to the surface desired to be patterned,
iv. Focusing quantum dots through the holes that define the sub-pixel by means of electric force, and thereby patterning the majority of the quantum dots on the desired electrodes by means of the electrical charges accumulated thereon by the ionic lens in case the ionic lens is an insulator lens, and by means of the electrical potential applied thereon in case the ionic lens is a conductive lens,
v. Removing the layer acting as an ionic lens from the substrate surface by means of a suitable solvent, abrasive, or corrosive,
vi. Repeating the (i-v) steps for each type of quantum dots sequentially to create different sub-pixels.

2. A method according to claim 1, characterized in that, it comprises, before the quantum dots are sent to the prepared surface, the process steps of:
a) sending zinc oxide (ZnO), magnesium-doped zinc oxide (Mg-doped ZnO) or other nanoparticles that can facilitate the electron flow to quantum dots and act as electron transfer layer to the surface by electrospray ionization,
b) focusing the nanoparticles through the holes that define the sub-pixel by means of electrical force by the ionic lens and thereby patterning the majority of the quantum dots on the desired electrodes.

3. A method according to claim 1 or claim 2, characterized in that, the ionic lens is selected as an insulator lens that focuses by accumulating electrical charges.

4. A method according to claim 3, characterized in that, the insulator lens is selected from a polymeric material.

5. A method according to claim 4, characterized in that, said polymer has a photoresist structure.

6. A method according to claim 5, characterized in that, the patterning process of the insulator lens is performed by the photolithography method.

7. A method according to claim 4, characterized in that, the insulator lens made of polymeric material is in a structure with opening holes by pre-patterned with soft lithography.

8. A method according to claim 7, characterized in that, polymer is polydimethyl siloxane (PDMS).

9. A method according to claim 7, characterized in that, the patterned insulator lens is placed on the substrate surface, aligned in accordance with the electrodes on the substrate.

10. A method according to claim 1, characterized in that, the ionic lens has a metallic structure and focuses by applying a voltage.

11. A method according to claim 1, characterized in that, the substrate consists of a transparent material.

12. A method according to claim 11, characterized in that, the substrate is made of glass material.

13. A method according to claim 1, characterized in that, all or some of the electrodes used are transparent.

14. A method according to claim 13, characterized in that, transparent electrodes are metal.

15. A method according to claim 14, characterized in that, transparent metal electrodes are made of indium tin oxide (ITO) or very thin aluminum.

16. A method according to claim 1, characterized in that, the liquid solution (6) containing the quantum dots is selected from water, methanol, ethanol, other alcohols, acetonitrile, chloroform, hexane, octane, any alkane, or any organic solvent.

17. A method according to claim 1, characterized in that, the substrate used is flexible and/or wearable.

18. A method according to claim 1, characterized in that, the size of the sub-pixel (9) formed by the patterned quantum dots is smaller than the size of the holes (3) the ionic lens comprises, by means of the focusing process.

19. A patterning method for the production of electronic/electro-optical devices based on nanoparticles that can convert optical energy into electrical energy by photovoltaic or electrothermal mechanism, characterized by comprising the process steps of,
i. depositing the material that will form the ionic lens on a substrate, on which electrodes and/or additional materials that will facilitate the transmission of electric current have been previously treated,
ii. forming the desired sub-pixel pattern in the form of holes on the material that will form the ionic lens by patterning, and obtaining the ionic lens by aligning the holes that define the sub-pixel on the machined electrodes by using standard alignment methods,
iii. forming the electrically charged nanoparticles in air, in a pure and discrete manner from other materials, by passing the liquid solution containing nanoparticles that can convert optical energy into electrical energy by photovoltaic or electrothermal mechanism, through the process of electrospray ionization, and sending it to the surface desired to be patterned,
iv. Focusing the nanoparticles through the holes that define the sub-pixel by means of electric force, and thereby patterning the majority of the quantum dots on the desired electrodes by means of the electrical charges deposited thereon by the ionic lens in case the ionic lens is an insulator lens, and by means of the electrical potential applied thereon in case the ionic lens is a conductive lens,
v. Removing the layer acting as an ionic lens from the substrate surface by means of a suitable solvent, abrasive, or corrosive,
vi. Repeating the (i-v) steps for each type of nanoparticles sequentially to create different sub-pixels.

20. A method of producing a monochrome or multi-color display with both high display performance and high performance of each pixel, wherein both the cross-contamination between different sub-pixel types and contamination from chemicals used in production for each sub-pixel are low, electroluminescent quantum dots consisting of pixels containing quantum dots are deposited directly onto target pixels containing electrodes, characterized by comprising the process steps of,
a. depositing photoresist material on a substrate surface on which electrodes have been treated,
b. forming the desired sub-pixel pattern in the form of holes on the photoresist material by using the photolithography process, and obtaining the insulator lens,
c. aligning the holes that define sub-pixel on metal electrodes by using standard alignment methods,
d. sending zinc oxide (ZnO), magnesium-doped zinc oxide (Mg-doped ZnO) or other nanoparticles that can facilitate the electron flow to quantum dots and act as electron transfer layer to the surface by electrospray ionization,
e. focusing the nanoparticles through the holes that define the sub-pixel by electric force by means of the electric charges accumulated thereon by insulator lens, and thereby patterning the majority of the quantum dots on the desired electrodes,
f. while the same insulator lens is still on the surface, sending the desired type of quantum dots to the surface by electrospray ionization, such that the insulating lens focuses a large part of the quantum dots on the holes that define the sub-pixel, and thereby patterning the quantum dots on the electron transfer layer,
g. Removing the photoresist layer that acts as an insulator lens from the surface by means of a suitable solvent or photoresist remover,
h. Patterning the quantum dots by repeating the previous processing steps appropriately for each different type of quantum dots desired to be used,
i. After patterning, laying the hole transfer layer in a suitable gas environment and using a spinner,
j. laying the hole injection layer,
k. joining a substrate with electrodes on this stack that is formed.

21. A method according to claim 20, characterized in that, all or some of the electrodes are selected as transparent metal electrodes.

22. A method according to claim 20, characterized in that, all or one of the substrates is/are selected as transparent.

23. A monochrome or multicolor display obtained by a method according to claim 20.
